(19) United States
(12) Patent Application Publication
(10) Pub. No.: US 2026/0031789 A1
(43) Pub. Date: Jan. 29, 2026

(54) ACOUSTIC WAVE DEVICE AND ACOUSTIC WAVE DEVICE MANUFACTURING METHOD

(71) Applicant: Murata Manufacturing Co., Ltd., Nagaokakyo-shi (JP)

(72) Inventors: Takahiko YANAGITANI, Tokyo (JP); Satoshi TOKAI, Tokyo (JP); Yasumasa TANIGUCHI, Nagaokakyo-shi (JP); Hiromu OKUNAGA, Nagaokakyo-shi (JP); Katsuya DAIMON, Nagaokakyo-shi (JP); Norio Taniguchi, Nagaokakyo-shi (JP); Naohiro NODAKE, Nagaokakyo-shi (JP); Akihiro IYAMA, Nagaokakyo-shi (JP)

(21) Appl. No.: 19/273,566

(22) Filed: Jul. 18, 2025

(30) Foreign Application Priority Data
Jul. 23, 2024 (JP) 2024-118006

(51) Int. Cl. H03H 9/19; H03H 3/02; H03H 9/02; H03H 9/13

(52) U.S. Cl. CPC H03H 9/19; H03H 3/02; H03H 9/02023; H03H 9/13

(57) ABSTRACT

An acoustic wave device includes a support substrate including a first crystal axis, first and second intermediate layers, a piezoelectric layer including a second crystal axis, and a functional electrode on the piezoelectric layer. The support substrate, the first and second intermediate layers, and the piezoelectric layer are arranged in this order. The first crystal axis is inclined at a first inclination angle with respect to a direction normal to the support substrate. The second crystal axis is inclined at a second inclination angle with respect to a direction normal to the piezoelectric layer. The first and second inclination angles are equal to each other. Rotational symmetry of the piezoelectric layer with respect to the second crystal axis is equal to rotational symmetry of the support substrate with respect to the first crystal axis.

### CROSS REFERENCE TO RELATED APPLICATIONS

This application claims the benefit of priority to Japanese Patent Application No. 2024-118006 filed on Jul. 23, 2024. The entire contents of this application are hereby incorporated herein by reference.

### BACKGROUND OF THE INVENTION

### 1. Field of the Invention

The present invention relates to acoustic wave devices and acoustic wave device manufacturing methods.

### 2. Description of the Related Art

Japanese Unexamined Patent Application Publication No. 2004-297359 describes a bulk acoustic wave (BAW) filter including a piezoelectric layer formed of a monocrystal of lithium niobate (LiNbO₃). Lithium niobate has a trigonal crystalline structure with rotational symmetry of order 3 about the c axis. As for a film made of lithium niobate, piezoelectricity generated in a direction perpendicular to the film is higher when the c axis is oriented to a direction inclined from the direction perpendicular to the film than the one when the c axis is oriented to the direction perpendicular to the film, thus allowing a reduction in propagation loss in the BAW filter. Therefore, in the BAW filter described in Japanese Unexamined Patent Application Publication No. 2004-297359, one obtained by cutting a bulk monocrystal of lithium niobate into a plate shape so that the c axis is oriented to a direction inclined from the direction perpendicular to the film is used as a piezoelectric layer.

As a method of fabricating a piezoelectric layer, film-formation technology can be used on a substrate to form a film directly (without performing an operation of cutting a bulk monocrystal). If a film with the c axis (crystal axis) inclined from the direction perpendicular to the film can be obtained by using the above-described film-formation technology, the step of cutting a bulk monocrystal is not required, and the manufacturing process can be simplified. However, for example, if a lithium niobate film is formed on a substrate, the crystal axis is oriented to the direction perpendicular to the film (for example, see Japanese Unexamined Patent Application Publication No. 2008-013824), and a piezoelectric film with its crystal axis inclined from the direction perpendicular to the film cannot be obtained.

### SUMMARY OF THE INVENTION

Example embodiments of the present invention provide acoustic wave devices each made with a simplified manufacturing process and reduced propagation loss, and methods of manufacturing such acoustic wave devices.

An acoustic wave device according to an example embodiment of the present invention includes a support substrate including a first crystal axis, a first intermediate layer, a second intermediate layer, a piezoelectric layer including a second crystal axis, and a functional electrode on the piezoelectric layer. The support substrate, the first intermediate layer, the second intermediate layer, and the piezoelectric layer are arranged in this order. The first crystal axis is inclined at a first inclination angle with respect to a direction normal to the support substrate. The second crystal axis is inclined at a second inclination angle with respect to a direction normal to the piezoelectric layer. The second inclination angle is equal to the first inclination angle. Rotational symmetry of the piezoelectric layer with respect to the second crystal axis is equal to rotational symmetry of the support substrate with respect to the first crystal axis.

An acoustic wave device manufacturing method according to another example embodiment of the present invention includes forming a film of a first intermediate layer on a principal surface of a support substrate including a first crystal axis, forming a film of a second intermediate layer on a principal surface of the first intermediate layer after the forming the film of the first intermediate layer, forming a film of a piezoelectric layer including a second crystal axis on a principal surface of the second intermediate layer after the forming the film of the second intermediate layer, and forming a functional electrode on the piezoelectric layer. The first crystal axis is inclined at a first inclination angle with respect to a direction normal to the support substrate. The second crystal axis is inclined at a second inclination angle with respect to a direction normal to the piezoelectric layer. The second inclination angle is equal to the first inclination angle. Rotational symmetry of the piezoelectric layer with respect to the second crystal axis is equal to rotational symmetry of the support substrate with respect to the first crystal axis.

According to example embodiments of the present invention, it is possible to provide acoustic wave devices each made with a simplified manufacturing process and reduced propagation loss and methods of manufacturing such acoustic wave devices.

The above and other elements, features, steps, characteristics and advantages of the present invention will become more apparent from the following detailed description of the example embodiments with reference to the attached drawings.

### BRIEF DESCRIPTION OF THE DRAWINGS

FIGS. 1A and 1B show a plan view and a sectional view of an acoustic wave device according to an example embodiment of the present invention.

FIG. 2 is a pole figure of a (10-12) plane of a piezoelectric layer according to an example embodiment of the present invention.

FIG. 3A is a sectional view showing a support substrate preparing step in a method of manufacturing an acoustic wave device according to an example embodiment of the present invention.

FIG. 3B is a sectional view showing a first intermediate layer film-forming step in a method of manufacturing an acoustic wave device according to an example embodiment of the present invention.

FIG. 3C is a sectional view showing a second intermediate layer film-forming step in a method of manufacturing an acoustic wave device according to an example embodiment of the present invention.

FIG. 3D is a sectional view showing a piezoelectric layer film-forming step in a method of manufacturing an acoustic wave device according to an example embodiment of the present invention.

FIG. 3E is a sectional view showing an IDT electrode forming step in a method of manufacturing an acoustic wave device according to an example embodiment of the present invention.

FIG. 4 is a sectional view of an acoustic wave device according to a first modification of an example embodiment of the present invention.

FIG. 5 is a sectional view of an acoustic wave device according to a second modification of an example embodiment of the present invention.

FIG. 6 is a sectional view of an acoustic wave device according to a third modification of an example embodiment of the present invention.

FIG. 7 is a sectional view of an acoustic wave device according to a fourth modification of an example embodiment of the present invention.

### DETAILED DESCRIPTION OF THE EXAMPLE EMBODIMENTS

In the following, example embodiments of the present disclosure are described in detail with reference to the drawings. Each example embodiment described below is a comprehensive or specific example. Numerical values, shapes, materials, components, the arrangement and connection configuration of the components, and so forth described in the following example embodiments are merely examples and are not meant to restrict the present invention. Among the components in the following example embodiments, a component not described in an independent claim is described as an arbitrary or optional component. Also, the size or the ratio of the size of a component shown in the drawings is not necessarily strict.

Each drawing is a schematic drawing subjected to enhancement, omission, or ratio adjustment as required in order to describe the present invention and is not necessarily strictly shown, and the shape, positional relationship, and ratio may be different from actual ones. In each drawing, the same or corresponding structures are denoted by the same reference characters, and redundant description may be omitted or simplified.

In a circuitry structure in the present disclosure, “connected” includes not only a case of being directly connected via a connection terminal and/or wire conductor but also a case of being electrically connected via a matching element such as an inductor or capacitor or a switch circuit. “Connected between A and B” means “connected to both A and B between A and B”.

Also, a term indicating a relationship between elements, such as “parallel” and “perpendicular”, a term indicating the shape of an element, such as “rectangular”, and a numerical range represent not only a strict meaning but include a substantially equivalent range, for example, an error on the order of several percent.

Furthermore, in the present disclosure, “main component of a material” refers to a component with a ratio of occupying the material exceeding 50 weight percent. The main component may be present in any of a monocrystal, a polycrystal, and an amorphous state or in a mixed state thereof.

In a layer structure of an example embodiment of the present disclosure, “A layer is arranged on (principal surface C of) B layer” includes, in addition to a state in which A layer is arranged in contact with (principal surface C of) B layer, a state in which A layer is arranged above principal surface C not in contact with principal surface C (for example, A layer is stacked on another layer arranged in contact with principal surface C).

Also, in the present disclosure, for example, rotational symmetry of a support substrate 32 and a piezoelectric layer 31 can be obtained by the following method. When pole measurement of X-ray diffraction (XRD) is used and an appearing diffraction peak is corrected by an inclination of the axis, a polar figure with rotational symmetry with respect to the center appears. By measuring this polar figure with each of the support substrate 32 and the piezoelectric layer 31, rotational symmetry of each of the support substrate 32 and the piezoelectric layer 31 can be obtained. Furthermore, by locally using a transmission electron microscope (TEM) or scanning electron microscope (SEM), it is possible to obtain a diffraction pattern of electron beams corresponding to symmetry of the crystal structure. Therefore, by analyzing this diffraction pattern, rotational symmetry can be measured with high accuracy.

Also, in example embodiments of the present disclosure, the inclination angle of the orientated crystal axis may be directed to any direction. It is defined that inclination angles of two layers are equal to each other when a difference therebetween is within a range of about ±16°, for example. The difference between inclination angles of two layers is preferably within a range of, for example, about ±5°. For example, with the inclination angles of two layers shifted from each other, lattice misfits increase on an interface between the two layers. When the difference in the inclination angle is within about ±16°, an increase in lattice misfits is smaller than or equal to about 4%, for example. On the other hand, when the difference in the inclination angle is within about ±5°, an increase in lattice misfits is smaller than or equal to about 0.4% and have little influence, for example.

### EXAMPLE EMBODIMENTS

### 1. Structure of Acoustic Wave Device 1

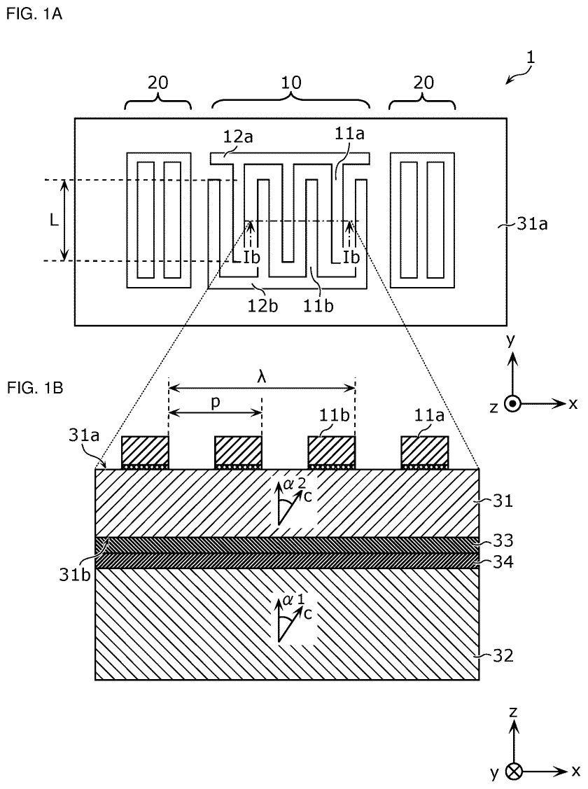

FIG. 1A is a plan view and FIG. 1B is a sectional view of an acoustic wave device 1 according to an example embodiment of the present invention. FIG. 1A is a view of a principal surface 31a of the piezoelectric layer 31 in plan view (perspective view) from a z-axis positive side. FIG. 1B is a sectional view taken along an Ib-Ib line in FIG. 1A as viewed from a y-axis negative side.

As shown in FIGS. 1A and 1B, the acoustic wave device 1 includes the support substrate 32, intermediate layers 33 and 34, the piezoelectric layer 31, an IDT electrode 10, and reflective electrodes 20. The support substrate 32, the intermediate layer 34, the intermediate layer 33, and the piezoelectric layer 31 are arranged in this order from a z-axis negative side toward a z-axis positive side. The acoustic wave device 1 shown in FIGS. 1A and 1B has a typical structure of an acoustic wave resonator of the acoustic wave device 1, and the number, length, and so forth of electrode fingers of the IDT electrode 10 and the reflective electrodes 20 are not limited to those shown.

The support substrate 32 supports the IDT electrode 10, the reflective electrodes 20, the piezoelectric layer 31, and the intermediate layers 33 and 34. The support substrate 32 includes a first crystal axis. The first crystal axis is inclined at an inclination angle α1 (first inclination angle) with respect to the direction normal to a principal surface of the support substrate 32. The support substrate 32 includes, for example, any of lithium niobate, lithium tantalate, sapphire, or silicon.

For example, when the support substrate 32 includes lithium niobate or lithium tantalate, the crystal of the support substrate 32 is trigonal, and has crystallinity with rotational symmetry of order 3 with respect to the first crystal axis (c axis).

Also, for example, when the support substrate 32 includes sapphire, the crystal of the support substrate 32 is hexagonal, and has crystallinity with rotational symmetry of order 6 with respect to the first crystal axis (c axis).

For the support substrate 32, for example, a material including any of the following as a main component may be used: a piezoelectric material such as aluminum nitride, aluminum oxide, or quartz, a ceramic such as magnesia, silicon nitride, silicon carbide, zirconia, cordierite, mullite, steatite, or forsterite, a dielectric such as diamond or glass, or a semiconductor such as gallium nitride.

The intermediate layer 34 is one example of a first intermediate layer, and is arranged between the support substrate 32 and the intermediate layer 33. The intermediate layer 33 is one example of a second intermediate layer, and is arranged between the intermediate layer 34 and the piezoelectric layer 31. The intermediate layers 33 and 34 each include metal. The intermediate layer 34 includes, for example, titanium (Ti), and the intermediate layer 33 includes, for example, platinum (Pt).

The intermediate layer 34 includes a third crystal axis inclined at an inclination angle α3 (third inclination angle) with respect to the direction normal to the intermediate layer 34, and the inclination angle α3 is preferably equal to the inclination angle α1. Also, the intermediate layer 33 includes a fourth crystal axis inclined at an inclination angle α4 (fourth inclination angle) with respect to the direction normal to the intermediate layer 33, and the inclination angle α4 is preferably equal to the inclination angle α1. According to this, an inclination angle α2 of a second crystal axis of the piezoelectric layer 31 can be made equal to the inclination angle α1 of the first crystal axis of the support substrate 32 with high accuracy.

Also, since two intermediate layers 33 and 34 including different metal materials are arranged between the support substrate 32 and the piezoelectric layer 31, the acoustic wave propagating through the piezoelectric layer 31 is efficiently reflected at the interface between the intermediate layers 33 and 34, and leakage to a support substrate 32 side can be effectively reduced or prevented. Furthermore, since thermal conductivity of the intermediate layers 33 and 34 is high, the heat dissipation property of the acoustic wave device 1 can be improved.

The piezoelectric layer 31 is arranged on the intermediate layer 33, and includes the second crystal axis. The second crystal axis is inclined at the inclination angle 2 (second inclination angle) with respect to the direction normal to the principal surfaces 31a and 31b of the piezoelectric layer 31. The piezoelectric layer 31 includes, for example, either lithium niobate or lithium tantalate. For the piezoelectric layer 31, a material such as, for example, quartz, potassium nitride (KN), aluminum nitride (AlN), scandium aluminum nitride (ScAlN), zinc oxide (ZnO), magnesium zinc oxide (MgZnO), or the like can be used. Here, the inclination angle α2 is equal to the inclination angle α1. That is, the piezoelectric layer 31 can be formed not with operation of cutting a bulk monocrystal but by forming a film on the support substrate 32 by using a thin-film formation method, and the inclination angle α2 of the piezoelectric layer 31 can be made equal to the inclination angle α1 of the support substrate 32.

When the piezoelectric layer 31 includes lithium niobate or lithium tantalate, the crystal of the piezoelectric layer 31 is trigonal, and has crystallinity with rotational symmetry of order 3 with respect to the second crystal axis (c axis). That is, since rotational symmetry of the piezoelectric layer 31 can be made equal to rotational symmetry of the support substrate 32, piezoelectricity of the piezoelectric layer 31 in the z-axis direction can be improved. Thus, the acoustic wave device 1 with a favorable fractional bandwidth and low loss can be provided.

When the piezoelectric layer 31 includes lithium niobate or lithium tantalate, the support substrate 32 preferably includes, for example, lithium niobate or lithium tantalate. According to this, the coefficients of linear expansion of the support substrate 32 and the piezoelectric layer 31 can be made equal to each other. Thus, frequency-temperature characteristics and mechanical strength of the acoustic wave device 1 can be improved.

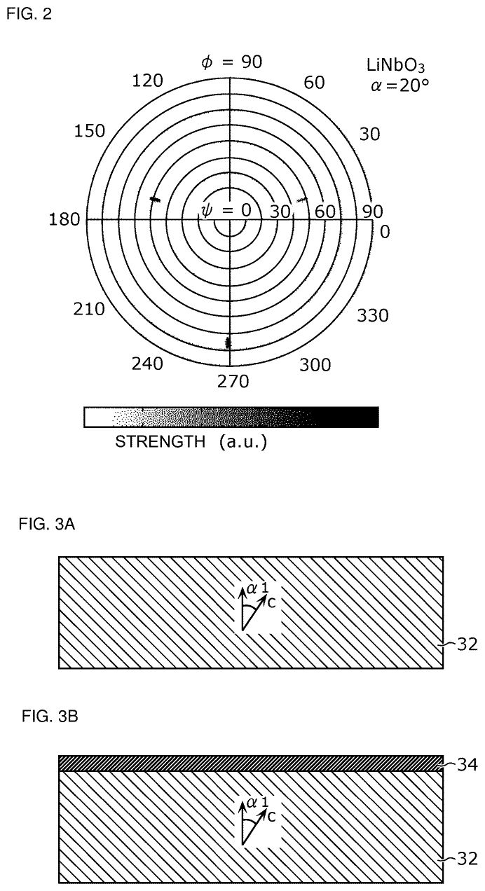

FIG. 2 is a pole figure of a (10-12) plane of the piezoelectric layer 31. In FIG. 2, for example, for the piezoelectric layer 31 with a target value of the inclination angle α2 being about 20°, a pole figure of a (10-12) plane obtained by X-ray diffraction is shown. As shown in FIG. 2, three poles indicating crystallinity with rotational symmetry of order 3 centering a point near an azimuthal angle Ψ of about 20° can be seen. With this, it can be determined that the piezoelectric layer 31 is oriented so as to be inclined at an inclination angle α2=, for example 20° with respect to the second crystal axis (c axis) and is oriented also to a direction in a plane perpendicular to the c axis.

The inclination angles α1 and α2 are, for example, larger than about 0° and smaller than about 90°. The inclination angle α2 is, for example, preferably about 10° to about 30°. According to this, piezoelectricity in a direction perpendicular to the principal surfaces 31a and 31b of the piezoelectric layer 31 can be further improved.

In the present example embodiment, the first crystal axis is defined as a crystal axis among one or more crystal axes of the support substrate 32, the crystal axis having an angle with respect to the direction normal to a principal surface (interface between the support substrate 32 and the intermediate layer 34) of the support substrate 32 being larger than about 0° and smaller than about 90°. Also, the second crystal axis is defined as a crystal axis among one or more crystal axes of the piezoelectric layer 31, the crystal axis having an angle with respect to the direction normal to the principal surfaces 31a and 31b of the piezoelectric layer 31 being larger than about 0° and smaller than about 90°. When one or more crystal axes having an angle with respect to the normal direction being larger than about 0° and smaller than about 90° are provided in the support substrate 32 and one or more crystal axes having an angle with respect to the normal direction being larger than about 0° and smaller than about 90° are present in the piezoelectric layer 31, it is only required that one of the one or more crystal axes of the support substrate 32 and one of the one or more crystal axes of the piezoelectric layer 31 have an equal angle with respect to the normal direction. In this case, the one of the one or more crystal axes of the support substrate 32 is defined as the first crystal axis, and the one of the one or more crystal axes of the piezoelectric layer 31 is defined as the second crystal axis.

When the support substrate 32 includes lithium niobate, lithium tantalate or sapphire, silicon carbide, lead titanate, or strontium titanate, for example, the first crystal axis among the one or more crystal axes of the support substrate 32 defines and functions as the c axis. Also, when the piezoelectric layer 31 includes lithium niobate or lithium tantalate, for example, the second crystal axis among the one or more crystal axes of the piezoelectric layer 31 defines and functions as the c axis. When the support substrate 32 includes lithium niobate, lithium tantalate or sapphire, silicon carbide, lead titanate, or strontium titanate, for example, the first crystal axis may be an axis other than the c axis. Also, when the piezoelectric layer 31 includes lithium niobate or lithium tantalate, for example, the second crystal axis may be an axis other than the c axis.

The IDT electrode 10 is one example of a functional electrode and, as shown in FIG. 1B, is arranged to the principal surface 31a. The IDT electrode 10 includes, as shown in FIG. 1A, a plurality of electrode fingers 11a and a plurality of electrode fingers 11b and busbar electrodes 12a and 12b. The plurality of electrode fingers 11a are arranged in parallel to each other. The plurality of electrode fingers 11b are arranged in parallel to each other. The plurality of electrode fingers 11a and the plurality of electrode fingers 11b are arranged in parallel to each other so as to be mutually interdigitated. The busbar electrode 12a is configured to connect one ends of the plurality of electrode fingers 11a. The busbar electrode 12a extends to a direction (x-axis direction) crossing an extending direction (y-axis direction of FIGS. 1A and 1B) of the electrode fingers 11a. The busbar electrode 12b is configured to connect one ends of the plurality of electrode fingers 11b. The busbar electrode 12b extends to a direction (x-axis direction) crossing an extending direction (y-axis direction of FIGS. 1A and 1B) of the plurality of electrode fingers 11b. The busbar electrode 12a and the busbar electrode 12b are opposed to each other across the plurality of electrode fingers 11a and the plurality of electrode fingers 11b. The other ends of the plurality of electrode fingers 11a are opposed to the busbar electrode 12b, and the other ends of the plurality of electrode fingers 11b are opposed to the busbar electrode 12a.

The reflective electrodes 20 are arranged on both sides of the IDT electrode 10 so as to be adjacent to the IDT electrode 10 in a direction (x-axis direction) perpendicular to the extending directions of the plurality of electrode fingers 11a and the plurality of electrode fingers 11b. The reflective electrodes 20 are configured so as to trap, in the IDT electrode 10, a predetermined high frequency signal resonating in the IDT electrode 10. In the acoustic wave device 1, the reflective electrodes 20 may be omitted.

The IDT electrode may be arranged on the principal surface 31b of the piezoelectric layer 31. Also, the IDT electrode 10 may be arranged not on the principal surface 31a of the piezoelectric layer 31 but only on the principal surface 31b. Also, a dielectric film or insulating film may be arranged between the IDT electrode 10 and the principal surface 31a.

The IDT electrode 10 has a multilayer structure including, for example, titanium (Ti), aluminum (Al), and titanium (Ti). The IDT electrode 10 is not limited to the above-described multilayer structure, and a material including at least one of copper (Cu), gold (Au), silver (Ag), molybdenum (Mo), tungsten (W), titanium (Ti), nickel (Ni), or chromium (Cr) or an alloy or multilayer film including several ones of these metals may be used.

According to the above-described structure, the IDT electrode 10 and the piezoelectric layer 31 define one surface acoustic wave resonator having a resonant frequency with a minimum impedance and an anti-resonant frequency with a maximum impedance.

In the acoustic wave device 1 according to the present example embodiment, the IDT electrode 10 may have a piston structure. Specifically, by thickening an end portion of each electrode finger (2D piston) or arranging a load film at a tip of each electrode finger (3D piston), a difference in acoustic velocity may be provided between a center portion of the electrode finger and a tip portion of the electrode finger. According to this, transverse-mode ripples occurring in the acoustic wave device 1 can be reduced or prevented.

According to the above-described structure of the acoustic wave device 1, for example, the piezoelectric layer 31 can be formed not by performing operation of cutting a bulk monocrystal, but by forming a film on the support substrate 32 by using a thin-film formation method, and the inclination angle α2 of the piezoelectric layer 31 can be made equal to the inclination angle α1 of the support substrate 32. Furthermore, since rotational symmetry of the piezoelectric layer 31 can be made equal to rotational symmetry of the support substrate 32, piezoelectricity of the piezoelectric layer 31 can be improved. Thus, the acoustic wave device 1 made with a simplified manufacturing process and reduced propagation loss can be provided.

It is preferable that, for example, the crystal lattice constant of the support substrate 32 is smaller than the crystal lattice constant of the intermediate layer 34, the crystal lattice constant of the intermediate layer 34 is smaller than the crystal lattice constant of the intermediate layer 33, and the crystal lattice constant of the intermediate layer 33 is smaller than the crystal lattice constant of the piezoelectric layer 31. When the support substrate 32 includes sapphire (crystal lattice constant: about 2.747 Å), the intermediate layer 34 includes titanium (crystal lattice constant: about 3.5900 Å), the intermediate layer 33 includes platinum (crystal lattice constant: about 3.9231 Å), and the piezoelectric layer 31 includes lithium niobate (crystal lattice constant: about 5.148 Å), the crystal lattice constants are in the order of the support substrate 32, the intermediate layer 34, the intermediate layer 33, and the piezoelectric layer 31 from smallest to largest. According to this, lattice mismatching at each interface between the above-described four layers can be minimized. Thus, crystallinity of the piezoelectric layer 31 can be further improved.

The crystal lattice constant of the support substrate 32 may be larger than the crystal lattice constant of the intermediate layer 34, the crystal lattice constant of the intermediate layer 34 may be larger than the crystal lattice constant of the intermediate layer 33, and the crystal lattice constant of the intermediate layer 33 may be larger than the crystal lattice constant of the piezoelectric layer 31. According to this, lattice mismatching at each interface between the above-described four layers can be minimized. Thus, crystallinity of the piezoelectric layer 31 can be further improved.

The multilayer body of the intermediate layers 33 and 34 may be arranged as repeated a plurality of times. According to this, the acoustic wave propagating through the piezoelectric layer 31 is efficiently reflected at the plurality of multilayer bodies, and leakage to a support substrate 32 side can be effectively reduced or prevented.

Either one of the intermediate layers 33 and 34 may be, for example, a semiconductor layer or an insulating layer not including metal. According to this, since two intermediate layers 33 and 34 including different materials are arranged between the support substrate 32 and the piezoelectric layer 31, the acoustic wave propagating through the piezoelectric layer 31 is efficiently reflected at the interface between the intermediate layers 33 and 34, and leakage to a support substrate 32 side can be effectively reduced or prevented.

Also, each of the intermediate layers 33 and 34 may be a layer including an insulator, for example. According to this, compared with a case in which the intermediate layers 33 and 34 are metal layers, the parasitic capacitance of the acoustic wave device 1 can be reduced. The intermediate layer 33 may be, for example, a low acoustic velocity layer with an acoustic velocity of a bulk wave lower than that of a bulk wave propagating through the piezoelectric layer 31, and the intermediate layer 34 may be, for example, a high acoustic velocity layer with an acoustic velocity of a bulk wave higher than that of a bulk wave propagating through the intermediate layer 33.

The low acoustic velocity layer includes, for example, at least one of silicon oxide or silicon oxynitride. Also, for the low acoustic velocity layer, for example, any of the following may be used: silicon oxide or silicon oxynitride, glass, lithium oxide, tantalum pentoxide, a dielectric such as a compound obtained by adding fluorine, carbon, or boron to silicon oxide, or a material including any of the above materials as a main component. According to the arrangement of the low acoustic velocity layer, unwanted waves in higher-order mode can be efficiently leaked to the intermediate layer 33.

The high acoustic velocity layer includes, for example, at least one of silicon nitride or silicon oxynitride. Also, for the high acoustic velocity layer, for example, any of the following may be used: a piezoelectric material such as silicon nitride, silicon oxynitride, aluminum nitride, aluminum oxide, lithium niobate, or quartz, a ceramic such as sapphire, magnesia, silicon carbide, zirconia, cordierite, mullite, steatite, or forsterite, a dielectric such as diamond-like carbon (DLC), diamond, or glass, a semiconductor such as silicon or gallium nitride, resin, or a material including any of the above materials as a main component. According to the arrangement of the high acoustic velocity layer, the acoustic wave propagating through the piezoelectric layer 31 is efficiently reflected in the high acoustic velocity layer, and leakage to a support substrate 32 side can be reduced or prevented.

The intermediate layers 33 and 34 may be an energy-trapping layer, for example. The energy-trapping layer is arranged between the support substrate 32 and the piezoelectric layer 31 and includes one or a plurality of layers, and the acoustic velocity of a bulk wave propagating through at least one of the layers is larger than the acoustic velocity of a bulk wave propagating near the piezoelectric layer 31. For example, the energy-trapping layer may have a multilayer structure including a low acoustic velocity layer and a high acoustic velocity layer. The low acoustic velocity layer is a film with an acoustic velocity of a bulk wave in the low acoustic velocity layer being lower than the acoustic velocity of an acoustic wave propagating though the piezoelectric layer. The high acoustic velocity layer is a film with an acoustic velocity of a bulk wave in the high acoustic velocity layer being higher than the acoustic velocity of an acoustic wave propagating though the piezoelectric layer. Also, the energy-trapping layer may be an acoustic impedance layer having a structure in which a low acoustic impedance layer having a relatively low acoustic impedance and a high acoustic impedance layer having a relatively high acoustic impedance are alternately stacked.

When a piezoelectric material having a hexagonal crystal structure is used as the piezoelectric layer 31, such as, for example, aluminum nitride (AlN), scandium aluminum nitride (ScAlN), zinc oxide (ZnO), or magnesium zinc oxide (MgZnO), sapphire, silicon carbide (SiC), or the like with rotational symmetry of order 6 about the c axis may be used as the support substrate 32. Also, when a piezoelectric material having a crystal structure with rotational symmetry of order 4 about the c axis is used as the piezoelectric layer 31, such as, for example, lead titanate (PbTiO₃), strontium titanate (SrTiO₃) with rotational symmetry of order 4 about the c axis may be used as the support substrate 32.

### 2. Method of Manufacturing Acoustic Wave Device 1

Next, an example of a method of manufacturing the acoustic wave device 1 is described.

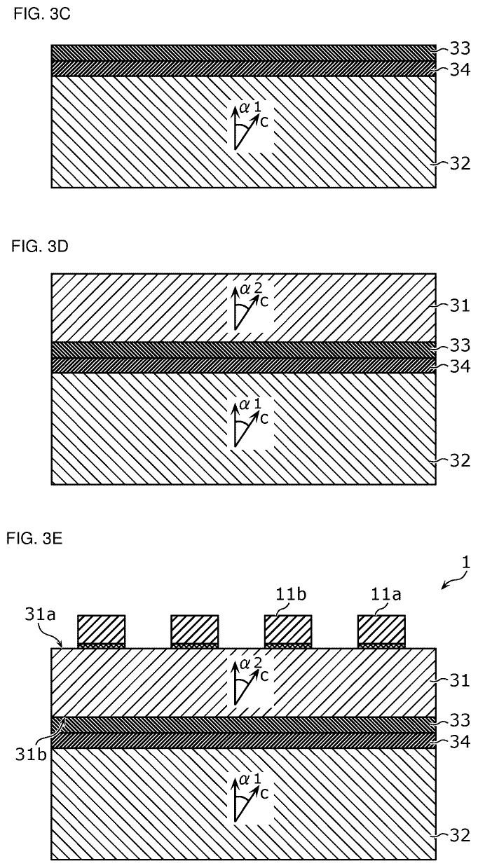

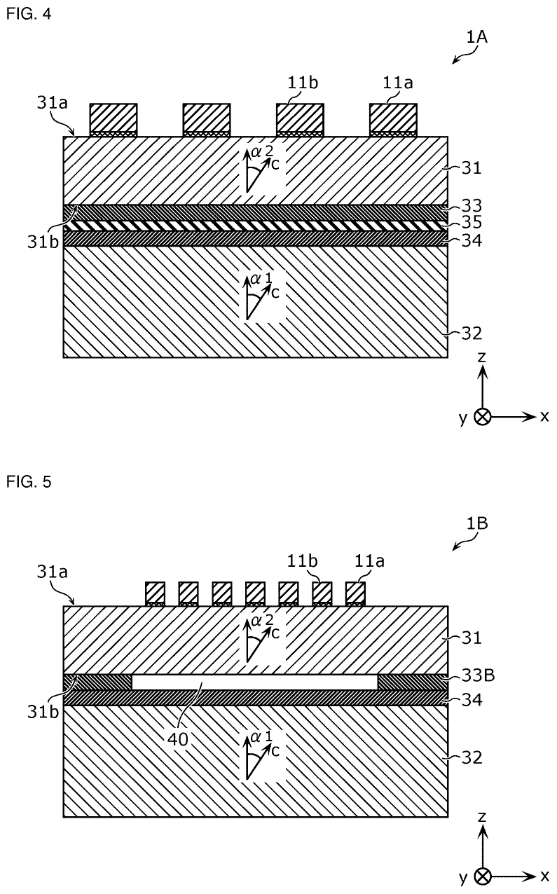

First, the support substrate 32 including the first crystal axis (c axis) inclined by the inclination angle α1 from the direction normal to the principal surface of the support substrate 32 is prepared (support substrate preparing step). FIG. 3A is a sectional view showing a support substrate preparing step in the method of manufacturing the acoustic wave device 1 according to the present example embodiment. More specifically, an example in which the support substrate 32 includes lithium niobate is exemplarily described. A monocrystal of lithium niobate with the first crystal axis (c axis) inclined by the inclination angle α1 is prepared. The crystal of lithium niobate is trigonal, and has rotational symmetry of order 3 about the first crystal axis (c axis). The monocrystal of lithium niobate can be obtained by, for example, cutting by a cutting machine using a laser beam or diamond wire saw. Since the support substrate 32 is sufficiently thicker than the piezoelectric layer 31, an operation of cutting the bulk monocrystal of the support substrate 32 is easier than an operation of cutting the piezoelectric layer 31 from the bulk monocrystal into a film shape (plate shape).

Next, a film of the intermediate layer 34 is formed on the principal surface of the support substrate 32 (first intermediate layer film-forming step). FIG. 3B is a sectional view showing a first intermediate layer film-forming step in the method of manufacturing the acoustic wave device 1 according to the present example embodiment. More specifically, an example in which the intermediate layer 34 includes titanium is exemplarily described. A titanium thin film is formed by, for example, sputtering. Here, the formed film of the intermediate layer 34 includes a third crystal axis inclined at the inclination angle α3 with respect to the direction normal to the intermediate layer 34, and the inclination angle α3 is preferably equal to the inclination angle α1. That is, in the first intermediate layer film-forming step, the titanium thin film is preferably epitaxially grown on the support substrate 32.

Next, a film of the intermediate layer 33 is formed on the principal surface of the intermediate layer 34 (second intermediate layer film-forming step). FIG. 3C is a sectional view showing a second intermediate layer film-forming step in the method of manufacturing the acoustic wave device 1 according to the present example embodiment. More specifically, for example, a case in which the intermediate layer 33 includes platinum is exemplarily described. A platinum thin film is formed by, for example, sputtering. Here, the formed film of the intermediate layer 33 includes a fourth crystal axis inclined at the inclination angle α4 with respect to the direction normal to the intermediate layer 33, and the inclination angle α4 is preferably equal to the inclination angle α1. That is, in the second intermediate layer film-forming step, the platinum thin film is preferably epitaxially grown on titanium thin film.

Next, a film of the piezoelectric layer 31 including the second crystal axis (c axis) is formed on the principal surface of the intermediate layer 33 (piezoelectric layer film-forming step). FIG. 3D is a sectional view showing a piezoelectric layer film-forming step in the method of manufacturing the acoustic wave device 1 according to the example embodiment. More specifically, a case in which the piezoelectric layer 31 includes lithium niobate is exemplarily described. The crystal of lithium niobate is trigonal, and has rotational symmetry of order 3 about the second crystal axis (c axis). When a film made of lithium niobate is formed on the front surface of the intermediate layers 33 and 34 crystally grown so that the orientation is aligned with the c-axis direction of the support substrate 32, crystal growth is made so that the c axis of lithium niobate is aligned with the c axis of sapphire and the orientation of the intermediate layers 33 and 34. As a result, the piezoelectric layer 31 with the second crystal axis (c axis) of lithium niobate inclined by the inclination angle α1 with respect to a direction perpendicular to the principal surfaces 31a and 31b can be obtained.

As a metal element of the intermediate layers 34 and 33, in place of titanium and platinum, a metal having a crystal structure of a 2face-centered cubic lattice may be used, for example, gold (Au), aluminum (Al), copper (Cu), silver (Ag), or iridium (Ir).

Lastly, the IDT electrode 10 is formed on the piezoelectric layer 31 (IDT electrode forming step). FIG. 3E is a sectional view showing the IDT electrode forming step in the method of manufacturing the acoustic wave device 1 according to the present example embodiment.

According to the above-described method of manufacturing the acoustic wave device 1, the piezoelectric layer 31 can be formed not by cutting a bulk monocrystal but by being epitaxially grown on the support substrate 32 by using a thin-film formation method, and the inclination angle α2 of the piezoelectric layer 31 can be made equal to the inclination angle α1 of the support substrate 32. Furthermore, since rotational symmetry of the piezoelectric layer 31 can be made equal to rotational symmetry of the support substrate 32, piezoelectricity of the piezoelectric layer 31 can be improved. Thus, the acoustic wave device 1 made with a simplified manufacturing process and reduced propagation loss can be provided.

### 3. Structure of Acoustic Wave Device 1A According to First Modification

FIG. 4 is a sectional view of an acoustic wave device 1A according to a first modification of an example embodiment of the present invention. As shown in FIG. 4, the acoustic wave device 1A according to the first modification includes the support substrate 32, the intermediate layers 33 and 34, a diffusion prevention film 35, the piezoelectric layer 31, the IDT electrode 10, and the reflective electrodes 20. The acoustic wave device 1A according to the present modification is different compared with the acoustic wave device 1 according to the above-described example embodiment in that the diffusion prevention film 35 is included. Thus, in the following, as for the acoustic wave device 1A according to the present modification, description of structures the same or substantially the same as those of the acoustic wave device 1 according to the above-described example embodiment is omitted, and different structures are mainly described.

The intermediate layer 34 is one example of a first intermediate layer, and is arranged between the support substrate 32 and the intermediate layer 33. The intermediate layer 33 is one example of a second intermediate layer, and is arranged between the intermediate layer 34 and the piezoelectric layer 31. The intermediate layers 33 and 34 each include metal. The intermediate layer 34 includes, for example, aluminum (Al), and the intermediate layer 33 includes, for example, platinum (Pt).

The diffusion prevention film 35 is arranged between the intermediate layer 34 and the intermediate layer 33. The diffusion prevention film 35 includes, for example, titanium (Ti).

According to this, the piezoelectric layer 31 can be formed not by cutting a bulk monocrystal but by being epitaxially grown on the support substrate 32 by using a thin-film formation method, and the inclination angle α2 of the piezoelectric layer 31 can be made equal to the inclination angle α1 of the support substrate 32. Furthermore, since rotational symmetry of the piezoelectric layer 31 can be made equal to rotational symmetry of the support substrate 32, piezoelectricity of the piezoelectric layer 31 can be improved. Thus, the acoustic wave device 1A made with a simplified manufacturing process and reduced propagation loss can be provided.

Also, with the diffusion prevention film 35, diffusion of aluminum elements of the intermediate layer 34 and platinum elements of the intermediate layer 33 can be prevented, and a large difference in acoustic impedance between the intermediate layers 33 (platinum) and 34 (aluminum) can be ensured. Thus, the acoustic wave propagating through the piezoelectric layer 31 is efficiently reflected at the interface between the intermediate layers 33 and 34, and leakage to a support substrate 32 side can be effectively reduced or prevented.

### 4. Structure of Acoustic Wave Device 1B According to Second Modification

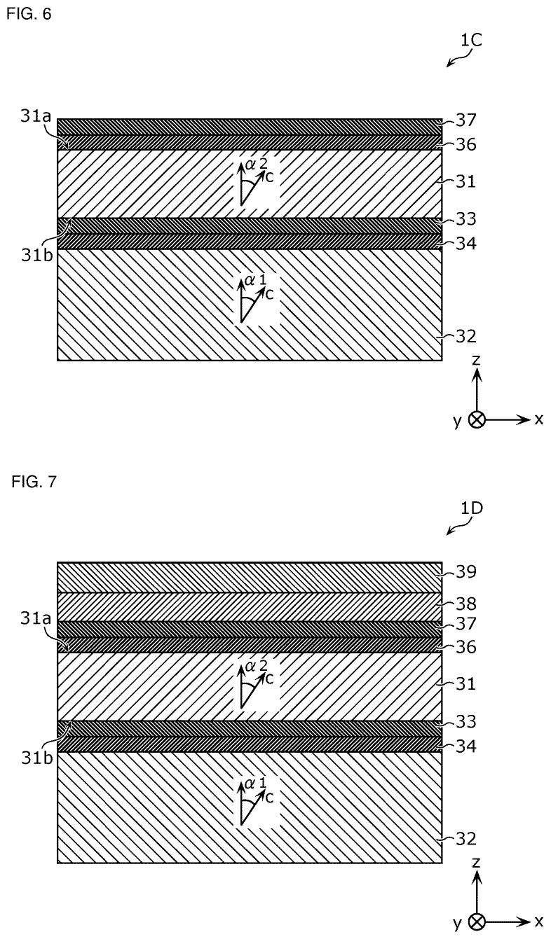

FIG. 5 is a sectional view of an acoustic wave device 1B according to a second modification of an example embodiment of the present invention. As shown in FIG. 5, the acoustic wave device 1B according to the second modification includes the support substrate 32, intermediate layers 33B and 34, the piezoelectric layer 31, the IDT electrode 10, and the reflective electrodes 20. The acoustic wave device 1B according to the present modification is different compared with the acoustic wave device 1 according to the above-described example embodiment in that a gap 40 is provided in the intermediate layer 33B. Thus, in the following, as for the acoustic wave device 1B according to the present modification, description of structures the same or substantially the same as those of the acoustic wave device 1 according to the above-described example embodiment is omitted, and different structures are mainly described.

The intermediate layer 34 is one example of a first intermediate layer, and is arranged between the support substrate 32 and the intermediate layer 33B. The intermediate layer 33B is one example of a second intermediate layer, and is arranged between the intermediate layer 34 and the piezoelectric layer 31. The intermediate layer 34 includes, for example, metal, and the intermediate layer 33B includes, for example, a metal oxide.

Also, the gap 40 is provided between the intermediate layer 34 and the piezoelectric layer 31 at a position overlapping the IDT electrode 10 when the piezoelectric layer 31 is viewed in plan view. The intermediate layer 33B includes, for example, zinc oxide (ZnO), and defines and functions also as a sacrificial layer for providing the gap 40.

The piezoelectric layer 31 is arranged on the intermediate layer 33B, and includes a second crystal axis. The second crystal axis is inclined at the inclination angle α2 (second inclination angle) with respect to the direction normal to the principal surfaces 31a and 31b of the piezoelectric layer 31. Here, the inclination angle α2 is equal to the inclination angle α1 of the first crystal axis of the support substrate 32. Also, when the thickness of the piezoelectric layer 31 (in the z-axis direction) is d and the electrode finger pitch of the IDT electrode 10 is p, a normalized film thickness d/p of the piezoelectric layer 31 is, for example, smaller than or equal to about 0.5.

With the normalized film thickness d/p of the piezoelectric layer 31 being smaller than or equal to about 0.5 and with the gap 40 being provided, the acoustic wave device 1B defines and functions a laterally excited bulk acoustic resonator (XBAR).

According to this, the piezoelectric layer 31 can be formed not by cutting a bulk monocrystal but by being epitaxially grown on the support substrate 32 by using a thin-film formation method, and the inclination angle 2 of the piezoelectric layer 31 can be made equal to the inclination angle α1 of the support substrate 32. Furthermore, since rotational symmetry of the piezoelectric layer 31 can be made equal to rotational symmetry of the support substrate 32, piezoelectricity of the piezoelectric layer 31 can be improved. The gap 40 and the intermediate layer 34 are arranged between the support substrate 32 and the piezoelectric layer 31. Thus, the acoustic wave propagating through the piezoelectric layer 31 is efficiently reflected at the gap 40 and the intermediate layer 34, and leakage to a support substrate 32 side can be effectively reduced or prevented. Thus, the XBAR acoustic wave device 1B made with a simplified manufacturing process and reduced propagation loss can be provided.

### 5. Structure of Acoustic Wave Device 1C According to Third Modification

FIG. 6 is a sectional view of an acoustic wave device 1C according to a third modification of the above-described example embodiment of the present invention. As shown in FIG. 6, the acoustic wave device 1C according to the third modification includes the support substrate 32, the intermediate layers 33 and 34, the piezoelectric layer 31, and conductive layers 36 and 37. The acoustic wave device 1C according to the present modification is different compared with the acoustic wave device 1 according to the above-described example embodiment in that the IDT electrode 10 and the reflective electrodes 20 are not arranged and the conductive layers 36 and 37 are included. Thus, in the following, as for the acoustic wave device 1C according to the present modification, description of structures the same or substantially the same as those of the acoustic wave device 1 according to the above-described example embodiment is omitted, and different structures are mainly described.

The intermediate layer 34 is one example of a first intermediate layer, and is arranged between the support substrate 32 and the intermediate layer 33. The intermediate layer 33 is one example of a second intermediate layer, and is arranged between the intermediate layer 34 and the piezoelectric layer 31. The intermediate layers 33 and 34 each include metal. The intermediate layer 34 includes, for example, titanium (Ti), and the intermediate layer 33 includes, for example, platinum (Pt).

Either one of the intermediate layers 33 and 34 may be a semiconductor layer or insulating layer not including metal.

The piezoelectric layer 31 is arranged on the intermediate layer 33, and includes the second crystal axis. The second crystal axis is inclined at the inclination angle α2 (second inclination angle) with respect to the direction normal to the principal surfaces 31a and 31b of the piezoelectric layer 31. The piezoelectric layer 31 includes, for example, either lithium niobate or lithium tantalate. For the piezoelectric layer 31, for example, a material such as quartz, potassium nitride (KN), aluminum nitride (AlN), scandium aluminum nitride (ScAlN), zinc oxide (ZnO), magnesium zinc oxide (MgZnO), or the like can be used. Here, the inclination angle α2 is equal to the inclination angle α1. That is, the piezoelectric layer 31 can be formed not by cutting a bulk monocrystal but by forming a film on the support substrate 32 by using a thin-film formation method, and the inclination angle α2 of the piezoelectric layer 31 can be made equal to the inclination angle α1 of the support substrate 32.

When the piezoelectric layer 31 includes lithium niobate or lithium tantalate, the crystal of the piezoelectric layer 31 is trigonal, and has crystallinity with rotational symmetry of order 3 with respect to the second crystal axis (c axis). That is, since rotational symmetry of the piezoelectric layer 31 can be made equal to rotational symmetry of the support substrate 32, piezoelectricity of the piezoelectric layer 31 can be improved. Thus, the acoustic wave device 1C with a favorable fractional bandwidth and low loss can be provided.

The conductive layer 36 is one example of a first conductive layer, and includes metal. The conductive layer 36 includes, for example, titanium (Ti). The conductive layer 37 is one example of a second conductive layer, and includes metal. The conductive layer 37 includes, for example, platinum (Pt).

The support substrate 32, the intermediate layer 34, the intermediate layer 33, the piezoelectric layer 31, the conductive layer 36, and the conductive layer 37 are arranged in this order.

In the present modification, a functional electrode is a multilayer body including the intermediate layers 33 and 34, the piezoelectric layer 31, and the conductive layers 36 and 37. That is, the functional electrode includes the conductive layers 36 and 37.

According to the above-described structure, the acoustic wave device 1C defines and functions as a bulk acoustic wave resonator using a bulk acoustic wave (BAW) propagating to a direction perpendicular to the principal surfaces 31a and 31b between the intermediate layers 33 and 34 and the conductive layers 36 and 37.

In the acoustic wave device 1C, the conductive layer 37 may be omitted.

According to this, the piezoelectric layer 31 can be formed not by cutting a bulk monocrystal but by being epitaxially grown on the support substrate 32 by using a thin-film formation method, and the inclination angle α2 of the piezoelectric layer 31 can be made equal to the inclination angle α1 of the support substrate 32. Furthermore, since rotational symmetry of the piezoelectric layer 31 can be made equal to rotational symmetry of the support substrate 32, piezoelectricity of the piezoelectric layer 31 can be improved. Thus, the BAW acoustic wave device 1C made with a simplified manufacturing process and reduced propagation loss can be provided.

The acoustic wave device 1C according to the present modification may have an acoustic multilayer film structure in which a multilayer body including the intermediate layers 34 and 33 is repeated a plurality of times. According to this, the acoustic wave device 1C defines and functions as a BAW resonator of a solidly mounted resonator (SMR) type, and can trap the bulk acoustic wave above the acoustic multilayer film by using Bragg reflection by the acoustic multilayer film.

### 6. Structure of Acoustic Wave Device 1D According to Fourth Modification

FIG. 7 is a sectional view of an acoustic wave device 1D according to a fourth modification of the above-described example embodiment of the present invention. As shown in FIG. 7, the acoustic wave device 1D according to the fourth modification includes the support substrate 32, the intermediate layers 33 and 34, the piezoelectric layer 31, the conductive layers 36 and 37, and insulating layers 38 and 39. The acoustic wave device 1D according to the present modification is different compared with the acoustic wave device 1C according to the third modification in that the insulating layers 38 and 39 are included. Thus, in the following, as for the acoustic wave device 1D according to the present modification, description of structures the same or substantially the same those of the acoustic wave device 1C according to the third modification is omitted, and different structures are mainly described.

The insulating layer 38 is one example of a first insulating layer, and is a low acoustic velocity layer, for example, with an acoustic velocity of a bulk wave lower than that of a bulk wave propagating through the piezoelectric layer 31. The insulating layer 39 is one example of a second insulating layer, and is a high acoustic velocity layer, for example, with an acoustic velocity of a bulk wave higher than that of a bulk wave propagating through the insulating layer 38.

The support substrate 32, the intermediate layer 34, the intermediate layer 33, the piezoelectric layer 31, the conductive layers 36 and 37, and the insulating layers 38 and 39 are arranged in this order.

According to this, the arrangement of the insulating layers 38 and 39 can further reduce or prevent leakage of the bulk acoustic wave to the z-axis positive direction and provide the BAW-type acoustic wave device 1D with more reduced propagation loss.

### 7. Advantageous Effects, Etc.

As described above, the acoustic wave device 1 according to the above-described example embodiment includes the support substrate 32 including a first crystal axis, the intermediate layers 34 and 33, the piezoelectric layer 31 including a second crystal axis, and the functional electrode on the piezoelectric layer 31. The support substrate 32, the intermediate layer 34, the intermediate layer 33, and the piezoelectric layer 31 are arranged in this order. The first crystal axis is inclined at the inclination angle α1 with respect to a direction normal to the support substrate 32. The second crystal axis is inclined at the inclination angle α2 with respect to a direction normal to the piezoelectric layer 31. The inclination angle α2 is equal to the inclination angle α1. Rotational symmetry of the piezoelectric layer 31 with respect to the second crystal axis is equal to rotational symmetry of the support substrate 32 with respect to the first crystal axis.

According to the above-described structure of the acoustic wave device 1, the piezoelectric layer 31 can be formed not by cutting a bulk monocrystal but by forming a film on the support substrate 32 by using a thin-film formation method, and the inclination angle α2 of the piezoelectric layer 31 can be made equal to the inclination angle α1 of the support substrate 32. Furthermore, since the rotational symmetry of the piezoelectric layer 31 can be made equal to the rotational symmetry of the support substrate 32, piezoelectricity of the piezoelectric layer 31 can be improved. Also, since two intermediate layers 33 and 34 including different metal materials are arranged between the support substrate 32 and the piezoelectric layer 31, the acoustic wave propagating through the piezoelectric layer 31 is efficiently reflected at the interface between the intermediate layers 33 and 34, and leakage to a support substrate 32 side can be effectively reduced or prevented. Thus, the acoustic wave device 1 made with a simplified manufacturing process and reduced propagation loss can be provided.

Also, for example, in the acoustic wave device 1, the intermediate layer 34 includes a third crystal axis inclined at a third inclination angle with respect to a direction normal to the intermediate layer 34, the intermediate layer 33 includes a fourth crystal axis inclined at a fourth inclination angle with respect to a direction normal to the intermediate layer 33, and the third inclination angle and the fourth inclination angle are equal to the inclination angle α1.

According to this, the piezoelectric layer 31 can be formed not by cutting a bulk monocrystal but by forming a film on the support substrate 32 by using a thin-film formation method, and the inclination angle α2 of the second crystal axis of the piezoelectric layer 31 can be made equal to the inclination angle α1 of the first crystal axis of the support substrate 32 with high accuracy.

Also, for example, in the acoustic wave device 1, the piezoelectric layer 31 includes lithium niobate or lithium tantalate.

According to this, the acoustic wave device 1 with high piezoelectricity can be provided.

Also, for example, in the acoustic wave device 1, the support substrate 32 includes lithium niobate, lithium tantalate, sapphire, or silicon.

According to this, the piezoelectric layer 31 including lithium niobate or lithium tantalate with high piezoelectricity can be epitaxially grown.

Also, for example, in the acoustic wave device 1, the support substrate 32 and the piezoelectric layer 31 each have crystallinity with rotational symmetry of order 3.

According to this, the piezoelectric layer 31 including lithium niobate or lithium tantalate with high piezoelectricity can be epitaxially grown.

Also, for example, in the acoustic wave device 1, at least one of the intermediate layers 33 and 34 includes metal.

According to this, the heat dissipation property of the acoustic wave device 1 can be improved.

Also, for example, in the acoustic wave device 1, the intermediate layers 33 and 34 each include metal.

According to this, the heat dissipation property of the acoustic wave device 1 can be further improved.

Also, for example, in the acoustic wave device 1, a crystal lattice constant increases in the order of the support substrate 32, the intermediate layer 34, the intermediate layer 33, and the piezoelectric layer 31, or the crystal lattice constant decreases in the order of the support substrate 32, the intermediate layer 34, the intermediate layer 33, and the piezoelectric layer 31.

According to this, lattice mismatching at interfaces of the support substrate 32, the intermediate layer 34, the intermediate layer 33, and the piezoelectric layer 31 can be minimized. Thus, crystallinity of the piezoelectric layer 31 can be further improved.

Also, for example, in the acoustic wave device 1, the intermediate layer 34 includes titanium, and the intermediate layer 33 includes platinum.

Also, for example, in the acoustic wave device 1, the support substrate 32 includes sapphire, and the piezoelectric layer 31 includes lithium niobate.

According to this, since the crystal lattice constant can be set in the order of the support substrate 32, the intermediate layer 34, the intermediate layer 33, and the piezoelectric layer 31 from the smallest to largest, crystallinity of the piezoelectric layer 31 can be further improved.

Also, for example, the acoustic wave device 1A according to the first modification further includes the diffusion prevention film 35 arranged between the intermediate layer 34 and the intermediate layer 33.

According to this, the diffusion prevention film 35 can prevent metal diffusion at the interface between the intermediate layers 33 and 34. Thus, the acoustic wave propagating through the piezoelectric layer 31 is efficiently reflected at the interface between the intermediate layers 33 and 34, and leakage to a support substrate 32 side can be effectively reduced or prevented.

Also, for example, in the acoustic wave device 1A, the intermediate layer 34 includes aluminum, the intermediate layer 33 includes platinum, and the diffusion prevention film 35 includes titanium.

According to this, the diffusion prevention film 35 can prevent metal diffusion at the interface between the intermediate layers 33 and 34, and a large difference in acoustic impedance between the intermediate layers 33 and 34 can be ensured. Thus, the acoustic wave propagating through the piezoelectric layer 31 is efficiently reflected at the interface between the intermediate layers 33 and 34, and leakage to a support substrate 32 side can be effectively reduced or prevented.

Also, for example, in the acoustic wave device 1, either one of the intermediate layers 33 and 34 includes an insulating material.

According to this, compared with a case in which the intermediate layers 33 and 34 are metal layers, the parasitic capacitance of the acoustic wave device 1 can be reduced.

Also, for example, in the acoustic wave device 1, the intermediate layer 33 is a low acoustic velocity layer with an acoustic velocity of a bulk wave lower than an acoustic velocity of a bulk wave propagating through the piezoelectric layer 31, and the intermediate layer 34 is a high acoustic velocity layer with an acoustic velocity of a bulk wave higher than an acoustic velocity of a bulk wave propagating through the intermediate layer 33.

According to this, unwanted waves in a higher-order mode can be efficiently leaked to the intermediate layer 33. Also, the acoustic wave propagating through the piezoelectric layer 31 is efficiently reflected at the interface between the low acoustic velocity layer and the high acoustic velocity layer, and leakage to a support substrate 32 side can be reduced or prevented.

Also, for example, in the acoustic wave device 1, the functional electrode is the IDT electrode 10.

According to this, a surface acoustic wave resonator or an XBAR made with a simplified manufacturing process and reduced propagation loss can be provided.

Also, for example, in the acoustic wave device 1B according to the second modification, the gap 40 is provided between the intermediate layer 34 and the piezoelectric layer 31 at a position overlapping the IDT electrode 10 when the piezoelectric layer 31 is viewed in plan view, and when the piezoelectric layer 31 has a thickness d and the IDT electrode 10 has an electrode finger pitch p, d/p is smaller than or equal to about 0.5.

According to this, an XBAR made with a simplified manufacturing process and reduced propagation loss can be provided.

Also, for example, in the acoustic wave device 1C according to the third modification, either one of the intermediate layers 33 and 34 includes metal. The acoustic wave device 1C further includes the conductive layer 36 including metal. The support substrate 32, the intermediate layer 34, the intermediate layer 33, the piezoelectric layer 31, and the conductive layer 36 are arranged in this order.

According to this, the piezoelectric layer 31 can be formed not by cutting a bulk monocrystal but by being epitaxially grown on the support substrate 32 by using a thin-film formation method, and the inclination angle α2 of the piezoelectric layer 31 can be made equal to the inclination angle α1 of the support substrate 32. Furthermore, since rotational symmetry of the piezoelectric layer 31 can be made equal to rotational symmetry of the support substrate 32, piezoelectricity of the piezoelectric layer 31 can be improved. Thus, the BAW acoustic wave device 1C made with a simplified manufacturing process and reduced propagation loss can be provided.

Also, for example, in the acoustic wave device 1C, the functional electrode includes the conductive layer 36.

According to this, the BAW acoustic wave device 1C made with a simplified manufacturing process and reduced propagation loss can be provided.

Also, for example, the acoustic wave device 1D according to the fourth modification further includes the insulating layers 38 and 39 each including an insulating material. The support substrate 32, the intermediate layer 34, the intermediate layer 33, the piezoelectric layer 31, the conductive layers 36 and 37, and the insulating layers 38 and 39 are arranged in this order. The insulating layer 38 is a low acoustic velocity layer with an acoustic velocity of a bulk wave lower than an acoustic velocity of a bulk wave propagating through the piezoelectric layer 31. The insulating layer 39 is a high acoustic velocity layer with an acoustic velocity of a bulk wave higher than an acoustic velocity of a bulk wave propagating through the insulating layer 38.

According to this, the arrangement of the insulating layers 38 and 39 can further reduce or prevent leakage of the bulk acoustic wave to the z-axis positive direction and provide the BAW acoustic wave device 1D with further reduced propagation loss.

Also, a method of manufacturing the acoustic wave device 1 according to an example embodiment includes forming a film of the intermediate layer 34 on a principal surface of the support substrate 32 including a first crystal axis, forming a film of the intermediate layer 33 on a principal surface of the intermediate layer 34 after the forming the film of the intermediate layer 34, forming a film of the piezoelectric layer 31 including a second crystal axis on a principal surface of the intermediate layer 33 after the forming the film of the intermediate layer 33, and forming a functional electrode on the piezoelectric layer 31. The first crystal axis is inclined at the inclination angle α1 with respect to a direction normal to the support substrate 32. The second crystal axis is inclined at the inclination angle α2 with respect to a direction normal to the piezoelectric layer 31. The inclination angle α2 is equal to the inclination angle α1. Rotational symmetry of the piezoelectric layer 31 with respect to the second crystal axis is equal to rotational symmetry of the support substrate 32 with respect to the first crystal axis.

According to this, the piezoelectric layer 31 can be formed not by cutting a bulk monocrystal but by being epitaxially grown on the support substrate 32 by using a thin-film formation method, and the inclination angle α2 of the piezoelectric layer 31 can be made equal to the inclination angle α1 of the support substrate 32. Furthermore, since the rotational symmetry of the piezoelectric layer 31 can be made equal to the rotational symmetry of the support substrate 32, piezoelectricity of the piezoelectric layer 31 can be improved. Thus, the acoustic wave device 1 made with a simplified manufacturing process and reduced propagation loss can be provided.

### Other Example Embodiments

While the acoustic wave devices and acoustic wave device manufacturing methods according to example embodiments of the present invention and modifications thereof have been described above, the present invention is not restricted to the above-described example embodiments and modifications thereof. Another example embodiment achieved by combining any components in the above-described example embodiments and modifications thereof and a modification obtained by applying various modifications devised by a person skilled in the art within a range not deviating from the scope of the present invention to the above-described example embodiments and modifications thereof are also included in the present invention.

Example embodiments of the present invention can each be widely used as an acoustic wave device to be arranged to a front end portion in a communication device such as a cellular phone, for example.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a support substrate including a first crystal axis;
a first intermediate layer;
a second intermediate layer;
a piezoelectric layer including a second crystal axis; and
a functional electrode on the piezoelectric layer; wherein
the support substrate, the first intermediate layer, the second intermediate layer, and the piezoelectric layer are arranged in this order;
the first crystal axis is inclined at a first inclination angle with respect to a direction normal to the support substrate;
the second crystal axis is inclined at a second inclination angle with respect to a direction normal to the piezoelectric layer;
the second inclination angle is equal to the first inclination angle; and
rotational symmetry of the piezoelectric layer with respect to the second crystal axis is equal to rotational symmetry of the support substrate with respect to the first crystal axis.

2. The acoustic wave device according to claim 1, wherein
the first intermediate layer includes a third crystal axis inclined at a third inclination angle with respect to a direction normal to the first intermediate layer;
the second intermediate layer includes a fourth crystal axis inclined at a fourth inclination angle with respect to a direction normal to the second intermediate layer; and
the third inclination angle and the fourth inclination angle are equal to the first inclination angle.

3. The acoustic wave device according to claim 1, wherein the piezoelectric layer includes lithium niobate or lithium tantalate.

4. The acoustic wave device according to claim 3, wherein the support substrate includes lithium niobate, lithium tantalate, sapphire, or silicon.

5. The acoustic wave device according to claim 3, wherein the support substrate and the piezoelectric layer each have crystallinity with rotational symmetry of order 3.

6. The acoustic wave device according to claim 1, wherein at least one of the first intermediate layer and the second intermediate layer includes metal.

7. The acoustic wave device according to claim 6, wherein the first intermediate layer and the second intermediate layer each include metal.

8. The acoustic wave device according to claim 7, wherein a crystal lattice constant increases in order of the support substrate, the first intermediate layer, the second intermediate layer, and the piezoelectric layer, or the crystal lattice constant decreases in order of the support substrate, the first intermediate layer, the second intermediate layer, and the piezoelectric layer.

9. The acoustic wave device according to claim 7, wherein
the first intermediate layer includes titanium; and
the second intermediate layer includes platinum.

10. The acoustic wave device according to claim 9, wherein
the support substrate includes sapphire; and
the piezoelectric layer includes lithium niobate.

11. The acoustic wave device according to claim 7, further comprising a diffusion prevention film between the first intermediate layer and the second intermediate layer.

12. The acoustic wave device according to claim 11, wherein
the first intermediate layer includes aluminum;
the second intermediate layer includes platinum; and
the diffusion prevention film includes titanium.

13. The acoustic wave device according to claim 1, wherein one of the first intermediate layer and the second intermediate layer includes an insulating material.

14. The acoustic wave device according to claim 13, wherein
the second intermediate layer includes a low acoustic velocity layer with an acoustic velocity of a bulk wave lower than an acoustic velocity of a bulk wave propagating through the piezoelectric layer; and
the first intermediate layer includes a high acoustic velocity layer with an acoustic velocity of a bulk wave higher than an acoustic velocity of a bulk wave propagating through the second intermediate layer.

15. The acoustic wave device according to claim 1, wherein the functional electrode includes an interdigital transducer (IDT) electrode.

16. The acoustic wave device according to claim 15, wherein
a gap is provided between the first intermediate layer and the piezoelectric layer at a position overlapping the IDT electrode when the piezoelectric layer is viewed in plan view; and
when the piezoelectric layer has a thickness d and the IDT electrode has an electrode finger pitch p, d/p is smaller than or equal to about 0.5.

17. The acoustic wave device according to claim 1, wherein
one of the first intermediate layer and the second intermediate layer includes metal; and
the acoustic wave device further includes a first conductive layer including metal; and
the support substrate, the first intermediate layer, the second intermediate layer, the piezoelectric layer, and the first conductive layer are arranged in this order.

18. The acoustic wave device according to claim 17, wherein the functional electrode includes the first conductive layer.

19. The acoustic wave device according to claim 17, further comprising:
a first insulating layer and a second insulating layer each including an insulating material; wherein
the support substrate, the first intermediate layer, the second intermediate layer, the piezoelectric layer, the first conductive layer, the second conductive layer, the first insulating layer, and the second insulating layer are arranged in this order;
the first insulating layer includes a low acoustic velocity layer with an acoustic velocity of a bulk wave lower than an acoustic velocity of a bulk wave propagating through the piezoelectric layer; and
the second insulating layer includes a high acoustic velocity layer with an acoustic velocity of a bulk wave higher than an acoustic velocity of a bulk wave propagating through the first insulating layer.

20. An acoustic wave device manufacturing method comprising:
forming a film of a first intermediate layer on a principal surface of a support substrate including a first crystal axis;
forming a film of a second intermediate layer on a principal surface of the first intermediate layer after the forming the film of the first intermediate layer;
forming a film of a piezoelectric layer including a second crystal axis on a principal surface of the second intermediate layer after the forming the film of the second intermediate layer; and
forming a functional electrode on the piezoelectric layer; wherein
the first crystal axis is inclined at a first inclination angle with respect to a direction normal to the support substrate;
the second crystal axis is inclined at a second inclination angle with respect to a direction normal to the piezoelectric layer;
the second inclination angle is equal to the first inclination angle; and
rotational symmetry of the piezoelectric layer with respect to the second crystal axis is equal to rotational symmetry of the support substrate with respect to the first crystal axis.
